(19) United States
(12) Patent Application Publication
(10) Pub. No.: US 2025/0349807 A1
(43) Pub. Date: Nov. 13, 2025

(54) SEMICONDUCTOR PACKAGE

(71) Applicant: SAMSUNG ELECTRONICS CO., LTD., Suwon-si (KR)

(72) Inventors: Jing Cheng LIN, Suwon-si (KR); Youngkun JEE, Suwon-si (KR)

(73) Assignee: SAMSUNG ELECTRONICS CO., LTD., Suwon-si (KR)

(21) Appl. No.: 18/973,701

(22) Filed: Dec. 9, 2024

(30) Foreign Application Priority Data
May 9, 2024 (KR) 10-2024-0061266

(51) Int. Cl. H01L 25/10; H01L 23/00; H01L 23/498; H10B 80/00

(52) U.S. Cl. CPC H01L 25/105; H01L 23/49816; H01L 24/13; H01L 24/14; H01L 24/16; H01L 24/32; H01L 24/73; H10B 80/00; H01L 2224/1357; H01L 2224/1403; H01L 2224/16227; H01L 2224/32225; H01L 2224/73204; H01L 2225/107; H01L 2924/381

(57) ABSTRACT

Provided is a semiconductor package including a lower semiconductor chip structure including: a plurality of lower dies stacked in a vertical direction; a lower post extending in the vertical direction from an upper surface of a lower die among the plurality of lower dies; and an insulating layer surrounding the lower post; an upper semiconductor chip structure above the lower semiconductor chip structure; and a vertical connection conductor on the lower semiconductor chip structure, wherein the vertical connection conductor is spaced apart from the upper semiconductor chip structure in a horizontal direction and is connected to the lower post.

### CROSS-REFERENCE TO RELATED APPLICATION

This application is based on and claims priority to Korean Patent Application No. 10-2024-0061266, filed on May 9, 2024, in the Korean Intellectual Property Office, the disclosure of which is incorporated by reference herein in its entirety.

### BACKGROUND

### 1. Field

The disclosure relates to a semiconductor package.

### 2. Description of Related Art

As the demand for thinner and smaller electronic products with higher capacity increases, various types of semiconductor packages are being developed. Among these various types of semiconductor packages, package technology that includes multiple chips in one package is being developed. However, due to technological limitations and thickness limitations of mobile devices, it is difficult to implement high-density wiring on boards using low-cost processes.

### SUMMARY

Provided is a semiconductor package with improved reliability.

According to an aspect of the disclosure, a semiconductor package includes: a lower semiconductor chip structure including: a plurality of lower dies stacked in a vertical direction; a lower post extending in the vertical direction from an upper surface of a lower die among the plurality of lower dies; and an insulating layer surrounding the lower post; an upper semiconductor chip structure above the lower semiconductor chip structure; and a vertical connection conductor on the lower semiconductor chip structure, wherein the vertical connection conductor is spaced apart from the upper semiconductor chip structure in a horizontal direction and is connected to the lower post.

According to an aspect of the disclosure, a semiconductor package includes: a lower memory chip structure including; a first lower die; a second lower die stacked on the first lower die a vertical direction; a first lower post extending from an upper surface of the first lower die in the vertical direction; a second lower post extending from an upper surface of the second lower die in the vertical direction; and an insulating layer extending along the upper surface of the second lower die and surrounding the second lower post; an upper memory chip structure on the lower memory chip structure; a first vertical connection conductor on the lower memory chip structure, wherein the first vertical connection conductor is spaced apart from the upper memory chip structure in a horizontal direction and is connected to the first lower post; and a second vertical connection conductor on the lower memory chip structure, wherein the second vertical connection conductor is spaced apart from the first vertical connection conductor in the horizontal direction and is connected to the second lower post.

According to an aspect of the disclosure, a semiconductor package includes: a lower memory chip structure including: a first lower die; a second lower die stacked on the first lower die in a vertical direction; a first lower post extending from an upper surface of the first lower die in the vertical direction; a second lower post extending from an upper surface of the second lower die in the vertical direction; and an insulating layer extending along the upper surface of the second lower die and surrounding the second lower post; an upper memory chip structure on the lower memory chip structure; a photo imageable dielectric (PID) layer between the upper memory chip structure and the lower memory chip structure; an outer molding layer sealing the upper memory chip structure; a redistribution structure on the upper memory chip structure; a first vertical connection conductor passing through the PID layer and the outer molding layer to connect the first lower post to the redistribution structure; and a second vertical connection conductor passing through the PID layer and the outer molding layer to connect the second lower post to the redistribution structure, wherein the insulating layer is between the PID layer and the second lower die.

### BRIEF DESCRIPTION OF DRAWINGS

The above and other aspects and features of certain embodiments of the present disclosure will be more apparent from the following description taken in conjunction with the accompanying drawings, in which:

FIG. 1 is a plan view of a semiconductor package according to one or more embodiments;

FIG. 2 is a cross-sectional view of a semiconductor package taken along line A-A′ in FIG. 1;

FIG. 3 is an enlarged view of area “CX1” in FIG. 2;

FIG. 4 is a cross-sectional view of a semiconductor package according to one or more embodiments;

FIG. 5 is a cross-sectional view of a semiconductor package according to one or more embodiments;

FIG. 6 is an enlarged view of area “CX2” in FIG. 5;

FIGS. 7 and 8 are cross-sectional views of a semiconductor package according to one or more embodiments;

FIGS. 9 through 26 are cross-sectional views sequentially illustrating a manufacturing process of the semiconductor package shown in FIG. 4; and

FIG. 27 is a schematic block diagram of a semiconductor package according to one or more embodiments.

### DETAILED DESCRIPTION

Hereinafter, one or more embodiments are described in detail with reference to the accompanying drawings. The same reference numerals are used for the same components in the drawings, and duplicate descriptions thereof are omitted.

As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

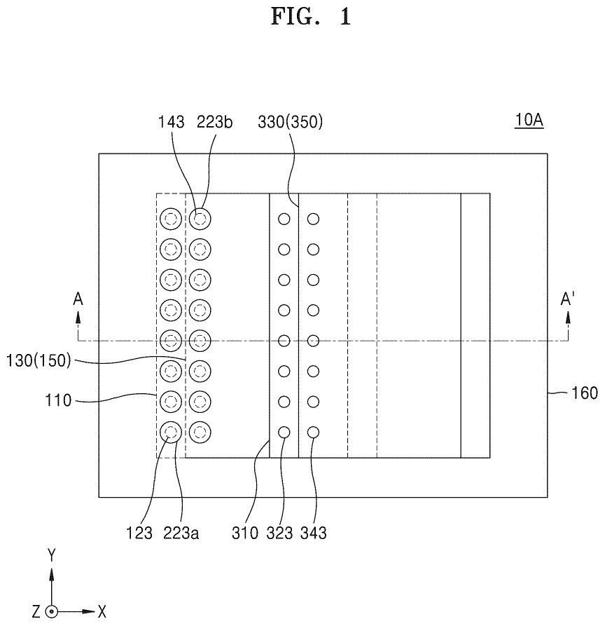

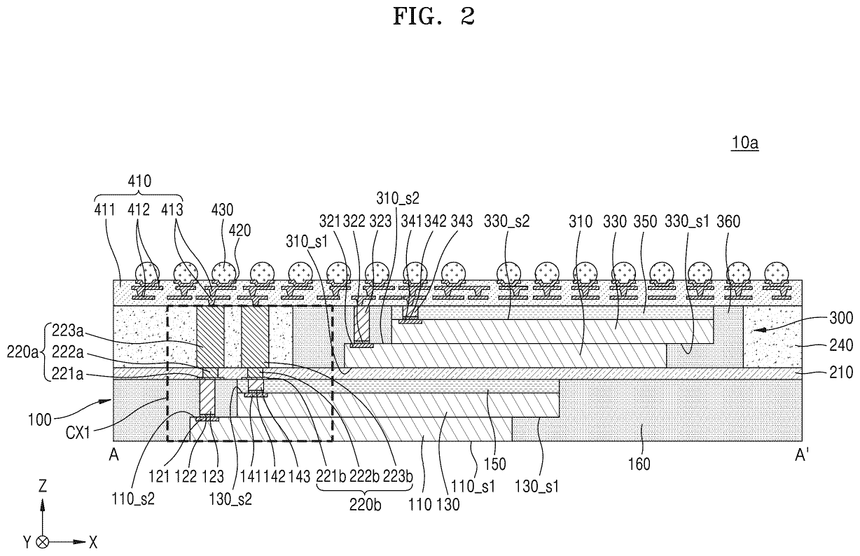

FIG. 1 is a plan view of a semiconductor package 10a according to one or more embodiments and FIG. 2 is a cross-sectional view of the semiconductor package 10a taken along line A-A′ in FIG. 1.

Referring to FIGS. 1 and 2, the semiconductor package 10a may include a lower semiconductor chip structure 100, a photo imageable dielectric (PID) layer 210, first and second vertical connection conductors 220a and 220b, an outer molding layer 240, an upper semiconductor chip structure 300, a redistribution structure 410, under bump metal layers 420, and external connection terminals 430.

According to one or more embodiments, the lower semiconductor chip structure 100 may include a first lower die 110, a first lower connection pad 121, a first lower metal seed layer 122, a first lower post 123, a second lower die 130, a second lower connection pad 141, a second lower metal seed layer 142, a second lower post 143, a lower insulating layer 150, and a lower molding layer 160.

The first lower die 110 and the second lower die 130 may be stacked in a stepwise manner. A first horizontal direction (X direction) may include a direction horizontal to surfaces of the first lower die 110 and the second lower die 130 and corresponding to a first step direction in which the first lower die 110 and the second lower die 130 are stacked. The second lower die 130 may be disposed on an active surface 110_s2 of the first lower die 110. The direction in which the first lower die 110 and the second lower die 130 overlap may be defined as a vertical direction (Z direction). Additionally, the direction which is horizontal to the surfaces of the first lower die 110 and the second lower die 130 and is perpendicular to the vertical direction (Z direction) may be defined as a second horizontal direction (Y direction). The active surface 110_s2 of the first lower die 110 refers to an upper surface thereof facing the second lower die 130 and an inactive surface 110_s1 of the first lower die 110 refers to an opposite surface to the active surface 110_s2 of the first lower die 110. In addition, an active surface 130_s2 of the second lower die 130 refers to an upper surface thereof facing the lower insulating layer 150 and an inactive surface 130_s1 of the second lower die 130 refers to an opposite surface to the active surface 130_s2 of the second lower die 130.

Each of the first lower die 110 and the second lower die 130 may include an integrated circuit (IC). The first lower die 110 and the second lower die 130 may have the active surfaces 110_s2 and 130_s2 on which the IC is formed and the inactive surfaces 110_s1 and 130_s1 opposite to the active surfaces 110_s2 and 130_s2, respectively. The lower semiconductor chip structure 100 may include the first and second lower connection pads 121 and 141 which are disposed on the active surfaces 110_s2 and 130_s2 of the first lower die 110 and the second lower die 130 and are capable of applying electrical signals to the first lower die 110 and the second lower die 130, respectively.

The first lower die 110 and the second lower die 130 may be horizontally offset so that the first lower connection pad 121 and the second lower connection pad 141 are exposed. For example, the first lower die 110 and the second lower die 130 may be horizontally offset and stacked toward one corner of the redistribution structure 410.

In one or more embodiments, the first lower die 110 and the second lower die 130 may be arranged to partially overlap with each other in the vertical direction (Z direction). For example, at least a portion of the second lower die 130 may be disposed on the first lower die 110 to overlap with at least a portion of the first lower die 110. The second lower die 130 may overlap with a portion of the first lower die 110.

The first lower die 110 and the second lower die 130, which are semiconductor substrates, may include a semiconductor material, such as a group IV semiconductor material, a group III-V semiconductor material, a group II-VI semiconductor material, or a combination thereof. The group IV semiconductor material may include, for example, silicon (Si), germanium (Ge), or a combination thereof. The group III-V semiconductor material may include, for example, gallium arsenide (GaAs), indium phosphorus (InP), gallium phosphorus (GaP), indium arsenide (InAs), indium antimony (InSb), indium gallium arsenide (InGaAs), or a combination thereof. The group II-VI semiconductor material may include, for example, zinc telluride (ZnTe), cadmium sulfide (CdS), or a combination thereof. The IC may include any type of IC including a memory circuit, a logic circuit, or a combination thereof. The memory circuit may include, for example, a dynamic random-access memory (DRAM) circuit, a static random-access memory (SRAM) circuit, a flash memory circuit, an electrically erasable and programmable read-only memory (EEPROM) circuit, a phase-change random-access memory (PRAM) circuit, a magnetic random-access memory (MRAM) circuit, a resistive random-access memory (RRAM) circuit, or a combination thereof. The logic circuit may include, for example, a central processing unit (CPU) circuit, a graphics processing unit (GPU) circuit, a controller circuit, an application specific integrated circuit (ASIC) circuit, an application processor (AP) circuit, or a combination thereof.

In one or more embodiments, the first lower die 110 and the second lower die 130 may include memory chips including memory circuits. The lower semiconductor chip structure 100 may include a memory chip structure composed of memory chips. The first upper die 310 and the second upper die 330 may also include memory chips including memory circuits and the upper semiconductor chip structure 300 may also include a memory chip structure composed of memory chips.

According to one or more embodiments, the lower semiconductor chip structure 100 may include a plurality of lower posts 123 and 143. The plurality of lower posts 123 and 143 may include a first lower post 123 connected to the first lower die 110 through the first lower connection pad 121 and a second lower post 143 connected to the second lower die 130 through the second lower connection pad 141.

The first lower post 123 may extend from the active surface 110_s2 of the first lower die 110 to the first vertical connection conductor 220a in the vertical direction (Z direction) and the second lower post 143 may extend from the active surface 130_s2 of the second lower die 130 to the second vertical connection conductor 220b in the vertical direction (Z direction). The first lower post 123 may pass through the lower molding layer 160 and the second lower post 143 may pass through the lower insulating layer 150. Since the active surface 110_s2 of the first lower die 110 is at a lower vertical level than the active surface 130_s2 of the second lower die 130, the length of the first lower post 123 in the vertical direction (Z direction) may be greater than the length of the second lower post 143 in the vertical direction (Z direction). An upper surface of the first lower post 123 and an upper surface of the second lower post 143 may be located on the same plane.

According to one or more embodiments, the upper surface of the first lower post 123 and the upper surface of the second lower post 143 may be located on the same plane as a lower surface of the PID layer 210, an upper surface of the lower insulating layer 150, and an upper surface of the lower molding layer 160. In particular, since an upper portion of the second lower post 143 and an upper portion of the lower insulating layer 150 are ground together in the process of forming the second lower post 143, the upper surface of the second lower post 143 and the upper surface of the lower insulating layer 150 may be located on the same plane. In addition, since an upper portion of the first lower post 123 and an upper portion of the lower molding layer 160 are ground together in the process of forming the first lower post 123, the upper surface of the first lower post 123 and the upper surface of the lower molding layer 160 may be located on the same plane.

In one or more embodiments, the cross-sectional shapes of the first lower post 123 and the second lower post 143 may vary and may include, for example, a circular or oval shape.

In one or more embodiments, the first lower post 123 and the second lower post 143 may have a tapered shape or a cylindrical shape.

For example, the first lower connection pad 121, the first lower post 123, the second lower connection pad 141, and the second lower post 143 may include a conductive material including copper (Cu), gold (Au), and silver (Ag), nickel (Ni), tungsten (W), aluminum (Al), or a combination thereof. However, the material included in the first lower connection pad 121, the first lower post 123, the second lower connection pad 141, and the second lower post 143 is not limited to the above and may include any conductive material.

The first lower post 123 and the second lower post 143 may further include a barrier material to prevent the conductive material from diffusing outward. The barrier material may include, for example, titanium (Ti), tantalum (Ta), titanium nitride (TiN), tantalum nitride (TaN), or a combination thereof.

The first lower metal seed layer 122 may be positioned between the first lower post 123 and the first lower connection pad 121 and the second lower metal seed layer 142 may be positioned between the second lower post 143 and the second lower connection pad 141. The cross-sectional shape of the first lower metal seed layer 122 matches the cross-sectional shape of the first lower post 123 and the cross-sectional shape of the second lower metal seed layer 142 matches the cross-sectional shape of the second lower post 143. The first lower metal seed layer 122 and the second lower metal seed layer 142 may be formed by using an electroless plating method. However, the first lower metal seed layer 122 and the second lower metal seed layer 142 may be omitted.

For example, the first lower metal seed layer 122 and the second lower metal seed layer 142 may include a Cu foil layer made of Cu foil.

The lower insulating layer 150 may extend along the active surface 130_s2 of the second lower die 130. The lower insulating layer 150 may surround the second lower post 143 and the second lower metal seed layer 142. The lower insulating layer 150 may completely overlap the second lower die 130, wherein an outer edge of the lower insulating layer 150 may coincide with an outer edge of the second lower die 130 from a horizontal view.

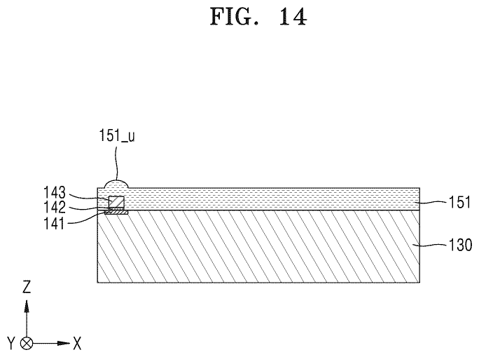

When the upper semiconductor chip structure 300 is stacked on the lower semiconductor chip structure 100, it is important to flatten the upper surface of the lower semiconductor chip structure 100. However, the second lower post 143 may protrude from the active surface 130_s2 of the second lower die 130. The roughness of the lower semiconductor chip structure 100 due to the protruding second lower post 143 may prevent the upper semiconductor chip structure 300 from being properly attached to the lower semiconductor chip structure 100. Therefore, it is important to flatten the upper surface of the lower semiconductor chip structure 100. A protrusion (e.g., protrusion 151_u in FIG. 14) on the upper surface of the lower semiconductor chip structure 100 that can be formed by the second lower post 143 may be removed by undergoing a grinding process after coating the lower insulating layer 150 surrounding the second lower post 143.

The lower insulating layer 150 may include, for example, an inorganic insulating material, an organic insulating material, or a combination thereof. The inorganic insulating material may include, for example, silicon oxide, silicon nitride, or a combination thereof. The organic insulating material may include, for example, polyimide (PI), epoxy resin, or a combination thereof. According to one or more embodiments, the thickness of the lower insulating layer 150 may be about 30 micrometers or less but is not necessarily limited thereto.

According to one or more embodiments, the lower molding layer 160 may be configured to seal the first lower die 110, the second lower die 130, the lower insulating layer 150, and the first lower post 123. The lower molding layer 160 may cover side surfaces of the first lower die 110, side surfaces of the second lower die 130, side surfaces of the lower insulating layer 150, and side surfaces of the first lower post 123. However, since the second lower post 143 is surrounded by the lower insulating layer 150, the lower molding layer 160 does not contact the second lower post 143. Additionally, since the upper surface of the lower insulating layer 150 is covered by the PID layer 210, the lower molding layer 160 may not contact the upper surface of the lower insulating layer 150.

The lower molding layer 160 may include, for example, a thermosetting resin, such as an epoxy resin, a thermoplastic resin, such as PI, or a resin including an inorganic filler, specifically, ABF, FR-4, BT, resin, and the like. Additionally, a molding material, such as EMC, or a photosensitive material, such as PIE, may be used.

The PID layer 210 may extend along the upper surface of the lower semiconductor chip structure 100. Specifically, the PID layer 210 may cover the upper surface of the lower insulating layer 150 and the upper surface of the lower molding layer 160. From a plan view, an outer perimeter of the PID layer 210 may overlap with an outer perimeter of the lower semiconductor chip structure 100. When the PID layer 210 is disposed on the lower semiconductor chip structure 100, a first lower vertical connection post 222a and a second lower vertical connection post 222b, each formed on the PID layer 210, may be formed at a finer pitch.

According to one or more embodiments, the upper semiconductor chip structure 300 may be mounted on the lower semiconductor chip structure 100. The upper semiconductor chip structure 300 may cover a portion of an upper surface of the PID layer 210. Since the configuration of the upper semiconductor chip structure 300 has many similarities to the configuration of the lower semiconductor chip structure 100, overlapping descriptions with those of the afore-mentioned configuration with reference to the lower semiconductor chip structure 100 may be simplified.

The upper semiconductor chip structure 300 may include a first upper die 310, a first upper connection pad 321, a first upper metal seed layer 322, a first upper post 323, a second upper die 330, a second upper connection pad 341, a second upper metal seed layer 342, a second upper post 343, an upper insulating layer 350, and an upper molding layer 360.

The first upper die 310 and the second upper die 330 may be stacked in steps in the first horizontal direction (X direction). The second upper die 330 may be disposed on an active surface 310_s2 of the first upper die 310. The active surface 310_s2 of the first upper die 310 refers to an upper surface thereof facing the second upper die 330 and an inactive surface 310_s1 of the first upper die 310 refers to an opposite surface to the active surface 310_s2 of the first upper die 310. In addition, an active surface 330_s2 of the second upper die 330 refers to an upper surface thereof facing the upper insulating layer 350 and an inactive surface 330_s1 of the second upper die 330 refers to an opposite surface to the active surface 330_s2 of the second upper die 330.

The first upper die 310 and the second upper die 330 may be horizontally offset so that the first upper connection pad 321 and the second upper connection pad 341 are exposed. For example, the first upper die 310 and the second upper die 330 may be horizontally offset and stacked toward one corner of the redistribution structure 410.

The first upper die 310 and the second upper die 330 may include semiconductor substrates which are substantially the same as the first lower die 110 and the second lower die 130. Accordingly, overlapping descriptions with the first lower die 110 and the second lower die 130 is omitted below.

According to one or more embodiments, the upper semiconductor chip structure 300 may include a plurality of upper posts 323 and 343. The plurality of upper posts 323 and 343 may include a first upper post 323 connected to the first upper die 310 through the first upper connection pad 321 and a second upper post 343 connected to the second upper die 330 through the second upper connection pad 341. The first upper post 323 may extend from the active surface 310_s2 of the first upper die 310 to the redistribution structure 410 in the vertical direction (Z direction) and the second upper post 343 may extend from the active surface 330_s2 of the second upper die 330 to the redistribution structure 410 in the vertical direction (Z direction). The first upper post 323 may pass through the upper molding layer 360 and the second upper post 343 may pass through the upper insulating layer 350. Since the active surface 310_s2 of the first upper die 310 is at a lower vertical level than the active surface 330_s2 of the second upper die 330, the length of the first upper post 323 in the vertical direction (Z direction) may be greater than the length of the second upper post 343 in the vertical direction (Z direction). An upper surface of the first upper post 323 and an upper surface of the second upper post 343 may be located on the same plane.

According to one or more embodiments, the upper surface of the first upper post 323 and the upper surface of the second upper post 343 may be located on the same plane as a lower surface of a redistribution insulating layer 411 of the redistribution structure 410, an upper surface of the upper insulating layer 350, and an upper surface of the upper molding layer 360. In particular, since an upper portion of the second upper post 343 and an upper portion of the upper insulating layer 350 are ground together in the process of forming the second upper post 343, the upper surface of the second upper post 343 and the upper surface of the upper insulating layer 350 may be located on the same plane. In addition, since an upper portion of the first upper post 323 and an upper portion of the upper molding layer 360 are ground together in the process of forming the first upper post 323, the upper surface of the first upper post 323 and the upper surface of the upper molding layer 360 may be located on the same plane.

In one or more embodiments, the cross-sectional shapes of the first upper post 323 and the second upper post 343 may vary and may include, for example, a circular or oval shape.

In one or more embodiments, the first upper post 323 and the second upper post 343 may have a tapered shape or a cylindrical shape.

Since the material constituting the first upper post 323 and the second upper post 343 is substantially the same as that of the first lower post 123 and the second lower post 143, detailed description thereof is omitted.

The first upper metal seed layer 322 may be positioned between the first upper post 323 and the first upper connection pad 321 and the second upper metal seed layer 342 may be positioned between the second upper post 343 and the second upper connection pad 341. The cross-sectional shape of the first upper metal seed layer 322 matches the cross-sectional shape of the first upper post 323 and the cross-sectional shape of the second upper metal seed layer 342 matches the cross-sectional shape of the second upper post 343. The first upper metal seed layer 322 and the second upper metal seed layer 342 may be formed by using an electroless plating method. However, the first upper metal seed layer 322 and the second upper metal seed layer 342 may be omitted.

Since the material constituting the first upper metal seed layer 322 and the second upper metal seed layer 342 is substantially the same as that of the first lower metal seed layer 122 and the second lower metal seed layer 142, detailed description thereof is omitted.

The upper insulating layer 350 may extend along the active surface 330_s2 of the second upper die 330. The upper insulating layer 350 may surround the second upper post 343 and the second upper metal seed layer 342. The upper insulating layer 350 may completely overlap the second upper die 330, wherein an outer edge of the upper insulating layer 350 may coincide with an outer edge of the second upper die 330 from a horizontal view.

When forming the redistribution structure 410 on the upper semiconductor chip structure 300, it is important to flatten an upper surface of the upper semiconductor chip structure 300. However, the second upper post 343 may protrude from the active surface 330_s2 of the second upper die 330. The roughness of the upper semiconductor chip structure 300 due to the protruding second upper post 343 may prevent the redistribution insulating layer 411 of the redistribution structure 410 from being properly attached to the upper semiconductor chip structure 300. Therefore, it is important to flatten the upper surface of the upper semiconductor chip structure 300. A protrusion on the upper surface of the upper semiconductor chip structure 300 that can be formed by the second upper post 343 may be removed by undergoing the grinding process after coating the upper insulating layer 350 surrounding the second upper post 343.

Since the material constituting the upper insulating layer 350 is substantially the same as that of the lower insulating layer 150, detailed description thereof is omitted. According to one or more embodiments, the thickness of the upper insulating layer 350 may be about 30 micrometers or less but is not necessarily limited thereto.

According to one or more embodiments, the upper molding layer 360 may be configured to seal the first upper die 310, the second upper die 330, the upper insulating layer 350, and the first upper post 323. The upper molding layer 360 may cover side surfaces of the first upper die 310, side surfaces of the second upper die 330, side surfaces of the upper insulating layer 350, and side surfaces of the first upper post 323. However, since the second upper post 343 is surrounded by the upper insulating layer 350, the upper molding layer 360 does not contact the second upper post 343. Additionally, since the upper surface of the upper insulating layer 350 is covered by the redistribution insulating layer 411, the upper molding layer 360 may not contact the upper surface of the upper insulating layer 350.

Since the material constituting the upper molding layer 360 is substantially the same as that of the lower molding layer 160, detailed description thereof is omitted.

According to one or more embodiments, the redistribution structure 410 may be arranged on the upper semiconductor chip structure 300. The active surface 330_s2 of the second upper die 330 may be arranged to face the redistribution structure 410.

The first lower post 123 may form an electrical path between the first lower die 110 and a redistribution layer 412 of the redistribution structure 410 through the first lower connection pad 121 and the second lower post 143 may form an electrical path between the second lower die 130 and a redistribution layer 412 of the redistribution structure 410 through the second lower connection pad 141. The redistribution structure 410 for redistribution may have a high wiring density without increasing the thickness of the semiconductor package 10a, enabling miniaturization of semiconductor packages. Since posts, rather than wire bonding using Au, are used for the electrical path to the redistribution layer 412, the process cost may be reduced and the shortest connection distance may be realized, contributing to improving the operation speed of semiconductor chips. According to the inventive concept, by forming multiple posts through electrolytic plating and finally forming a redistribution layer for rewiring the same, packaging technology that is cost-competitive and is capable of implementing multiple input/output (I/O) paths may be provided.

The redistribution structure 410 may include the redistribution insulating layer 411, redistribution layers 412, and redistribution vias 413. The redistribution structure 410 may rewire the first lower connection pad 121 of the first lower die 110, the second lower connection pad 141 of the second lower die 130, the first upper connection pad 321 of the first upper die 310, and the second upper connection pad 341 of the second upper die 330. The first lower connection pad 121, the second lower connection pad 141, the first upper connection pad 321, and the second upper connection pad 341 may be physically and/or electrically connected to the outside through the redistribution structure 410.

The redistribution insulating layer 411 may include an insulating material. The insulating material may include, for example, an inorganic insulating material, an organic insulating material, or a combination thereof. The inorganic insulating material may include, for example, silicon oxide, silicon nitride, or a combination thereof. The organic insulating material may include, for example, PI, epoxy resin, or a combination thereof.

Additionally, according to one or more embodiments, the redistribution insulating layer 411 may include a photosensitive insulating material, such as PID resin. In one or more embodiments, when the redistribution insulating layer 411 includes a photosensitive insulating material, the redistribution insulating layer 411 may be formed thinner and a fine pitch of the redistribution via 413 may be more easily achieved.

The redistribution layer 412 may rewire the first lower connection pad 121, the second lower connection pad 141, the first upper connection pad 321, and the second upper connection pad 341. The redistribution layer 412 may include Cu, Al, Ag, tin (Sn), Au, Ni, lead (Pb), Ti, or alloys thereof. The redistribution layer 412 may perform various functions depending on the design of the corresponding layer. For example, the redistribution layer 412 may include a ground pattern, a power pattern, a signal pattern, and the like. The signal pattern may include various signals, such as data signals, other than the ground pattern, the power pattern, and the like. The pattern may include wiring and pads.

The redistribution via 413 may electrically connect the redistribution layer 412, the first lower connection pad 121, the second lower connection pad 141, the first upper connection pad 321, and the second upper connection pad 341, which are formed at different layers. As a result, an electrical path may be formed within the redistribution structure 410. The redistribution via 413 may include a metal material, such as of Cu, Al, Ag, Sn, Au, Ni, Pb, Ti, or alloys thereof. The redistribution via 413 may include a field type filled with a metal material or may include a conformal type in which the metal material is formed along the wall of a via hole. The redistribution via 413 may have a tapered cross-sectional shape. For example, the redistribution via 413 may have a tapered shape with an upper width greater than a lower width based on the cross-section.

The redistribution insulation layer 411, the redistribution layers 412, and the redistribution vias 413 of the redistribution structure 410 may be composed of a greater number of layers than shown in the drawings. Alternatively, the redistribution insulation layer 411, the redistribution layers 412, and the redistribution vias 413 of the redistribution structure 410 may be composed of fewer layers than shown in the drawings.

According to one or more embodiments, the under bump metal layers 420 and the external connection terminals 430 may be disposed on the upper surface of the redistribution insulating layer 411 of the redistribution structure 410.

The external connection terminals 430 may physically and/or electrically connect the semiconductor package 10a to the outside. For example, the semiconductor package 10a may be mounted on a main board of an electronic device through the external connection terminals 430. The external connection terminals 430 may be electrically connected to the redistribution layers 412 through the under bump metal layers 420. The external connection terminals 430 may include a low melting point metal, for example, Sn or an alloy including Sn. The external connection terminals 430 may be formed of solders but are not limited thereto.

The external connection terminals 430 may include lands, balls, pins, and the like. The external connection terminals 430 may be formed in multiple layers or a single layer. When the external connection terminals 430 are formed in multiple layers, the external connection terminals 430 may include Cu pillars and solders. When the external connection terminals 430 are formed in a single layer, the external connection terminals 430 may include Sn—Ag solders or Cu but are not limited thereto. The number, spacing, and arrangement type of the external connection terminals 430 may vary.

According to one or more embodiments, the outer molding layer 240 between the PID layer 210 and the redistribution structure 410 may be configured to seal the first vertical connection conductor 220a, the second vertical connection conductor 220b, and the upper semiconductor chip structure 300. The outer molding layer 240 may cover the side surfaces of the upper molding layer 360. An upper surface of the outer molding layer 240 may contact the redistribution insulating layer 411 of the redistribution structure 410 and a lower surface of the outer molding layer 240 may contact the upper surface of the PID layer 210.

The length of the outer molding layer 240 in the vertical direction (Z direction) may be substantially the same as a vertical length of a first upper vertical connection post 223a of the first vertical connection conductor 220a and a vertical length of a second upper vertical connection post 223b of the second vertical connection conductor 220b.

According to one or more embodiments, the material constituting the outer molding layer 240 may be different from that of the upper molding layer 360.

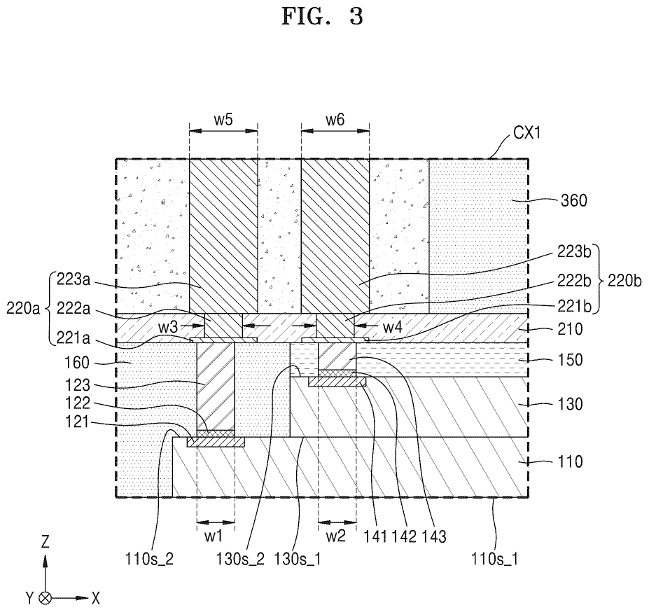

Detailed description of the first vertical connection conductor 220a and the second vertical connection conductor 220b may be made with reference to FIG. 3.

FIG. 3 is an enlarged view of area “CX1” in FIG. 2. Hereinafter, for convenience of explanation, the description may be made with reference to FIG. 3 along with FIG. 2.

According to one or more embodiments, the first vertical connection conductor 220a may include a first vertical connection pad 221a, the first lower vertical connection post 222a, and the first upper vertical connection post 223a. The second vertical connection conductor 220b may include a second vertical connection pad 221b, the second lower vertical connection post 222b, and the second upper vertical connection post 223b.

The first vertical connection pad 221a may be embedded in the PID layer 210 and electrically and physically connected to the first lower post 123. The second vertical connection pad 221b may be embedded in the PID layer 210 and electrically and physically connected to the second lower post 143. A lower surface of the first vertical connection pad 221a and a lower surface of the second vertical connection pad 221b may be located on the same plane as the lower surface of the PID layer 210. The thickness of the first vertical connection pad 221a and the second vertical connection pad 221b in the vertical direction (Z direction) may be relatively less than the thickness of the first lower vertical connection post 222a and the second lower vertical connection post 222b in the vertical direction (Z direction).

The first lower vertical connection post 222a may be embedded in the PID layer 210 and electrically and physically connected to the first vertical connection pad 221a and the first upper vertical connection post 223a. The second lower vertical connection post 222b may be embedded in the PID layer 210 and electrically and physically connected to the second vertical connection pad 221b and the second upper vertical connection post 223b. An upper surface of the first lower vertical connection post 222a and an upper surface of the second lower vertical connection post 222b may be located on the same plane as the upper surface of the PID layer 210.

The first upper vertical connection post 223a may be embedded in the outer molding layer 240 and electrically and physically connected to the first lower vertical connection post 222a and the redistribution structure 410. The second upper vertical connection post 223b may be embedded in the outer molding layer 240 and electrically and physically connected to the second lower vertical connection post 222b and the redistribution structure 410. An upper surface of the first upper vertical connection post 223a and an upper surface of the second upper vertical connection post 223b may be located on the same plane as the upper surface of the outer molding layer 240.

According to one or more embodiments, a width w3 of the first lower vertical connection post 222a in the lateral direction (X direction and/or Y direction) may be less than a width w5 of the first upper vertical connection post 223a in the lateral direction (X direction and/or Y direction). In addition, a width w4 of the second lower vertical connection post 222b in the lateral direction (X direction and/or Y direction) may be less than a width w6 of the second upper vertical connection post 223b in the lateral direction (X direction and/or Y direction). Accordingly, the maximum width of the first vertical connection conductor 220a may be defined as the maximum width w5 of the first upper vertical connection post 223a. Similarly, the maximum width of the second vertical connection conductor 220b may be defined as the maximum width w6 of the second upper vertical connection post 223b.

According to one or more embodiments, the maximum width of the first upper vertical connection post 223a in the lateral direction (X direction and/or Y direction) may be greater than the maximum width of the first lower post 123 in the lateral direction (X direction and/or Y direction). In addition, the maximum width of the second upper vertical connection post 223b in the lateral direction (X direction and/or Y direction) may be greater than the maximum width of the second lower post 143 in the lateral direction (X direction and/or Y direction). The first lower post 123 and the second lower post 143 may be formed to have a finer pitch because the first lower post 123 and the second lower post 143 are formed on the first lower die 110 and the second lower die 130. However, the first upper vertical connection post 223a and the second upper vertical connection post 223b may be formed to have a relatively wide pitch because the first upper vertical connection post 223a and the second upper vertical connection post 223b are formed on the lower semiconductor chip structure 100.

For example, the first vertical connection conductor 220a and the second vertical connection conductor 220b may include a conductive material including Cu, Au, Ag, Ni, W, Al, or a combination thereof. However, the material included in the first vertical connection conductor 220a and the second vertical connection conductor 220b is not limited to the above and may include any conductive material.

The first vertical connection conductor 220a and the second vertical connection conductor 220b may further include a barrier material to prevent the conductive material from diffusing outward. The barrier material may include, for example, Ti, Ta, TiN, TaN, or a combination thereof.

More flexible and diverse electrical wiring may be implemented from the lower semiconductor chip structure 100 to the redistribution structure 410 by arranging the first vertical connection conductor 220a and the second vertical connection conductor 220b, rather than connecting the first lower post 123 and the second lower post 143 directly to the redistribution structure 410.

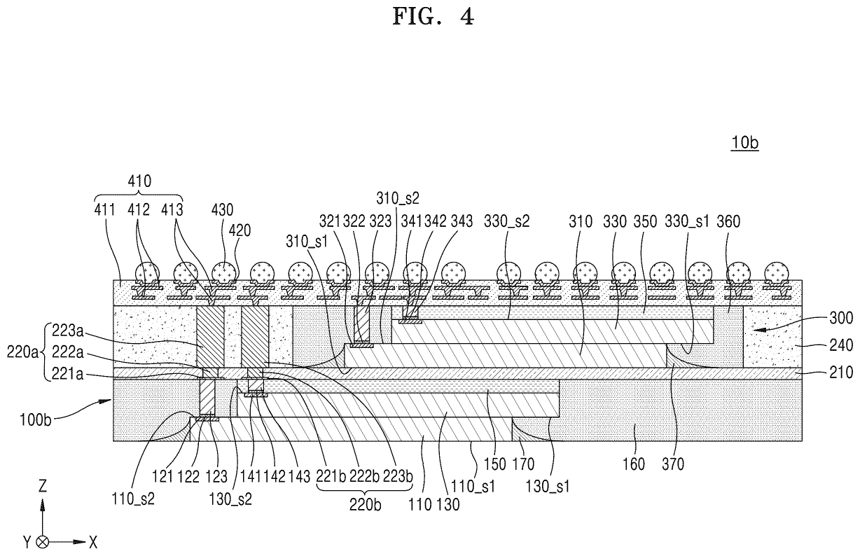

FIG. 4 is a cross-sectional view of a semiconductor package 10b according to another embodiment.

The semiconductor package 10b shown in FIG. 4 is almost identical or similar to the semiconductor package 10a shown in FIG. 2, except that a lower side support layer 170 is disposed on side surfaces of the first lower die 110 and an upper side support layer 370 is disposed on side surfaces of the first upper die 310. Accordingly, the description of the components already mentioned with reference to FIG. 2 is omitted or simplified.

Referring to FIG. 4, the lower side support layer 170 may be disposed on the side surfaces of the first lower die 110. Although not specifically shown in the drawings, a heat dissipation layer may be additionally arranged below the lower semiconductor chip structure 100b. The lower molding layer 160 may be bent due to warpage. As the lower molding layer 160 is bent, the first lower die 110 may be detached from the heat dissipation layer. Accordingly, to prevent the first lower die 110 from being detached from the heat dissipation layer, the lower side support layer 170 may fix the first lower die 110 to the heat dissipation layer.

The upper side support layer 370 may be disposed on the side surfaces of the first upper die 310. The first upper die 310 may be attached to the upper surface of the PID layer 210. The upper molding layer 360 may be bent due to warpage. As the upper molding layer 360 is bent, the first upper die 310 may be detached from the PID layer 210. Accordingly, to prevent the first upper die 310 from being detached from the PID layer 210, the upper side support layer 370 may fix the first upper die 310 to the PID layer 210.

The lower side support layer 170 may include a material having sufficient adhesive force to prevent the first lower die 110 from separating from the heat dissipation layer. Additionally, the upper side support layer 370 may include a material having sufficient adhesive force to prevent the first upper die 310 from separating from the PID layer 210.

The lower side support layer 170 and the upper side support layer 370 may include an underfill or other solid material to stabilize the first lower die 110 and the first upper die 310 in a state without twisting.

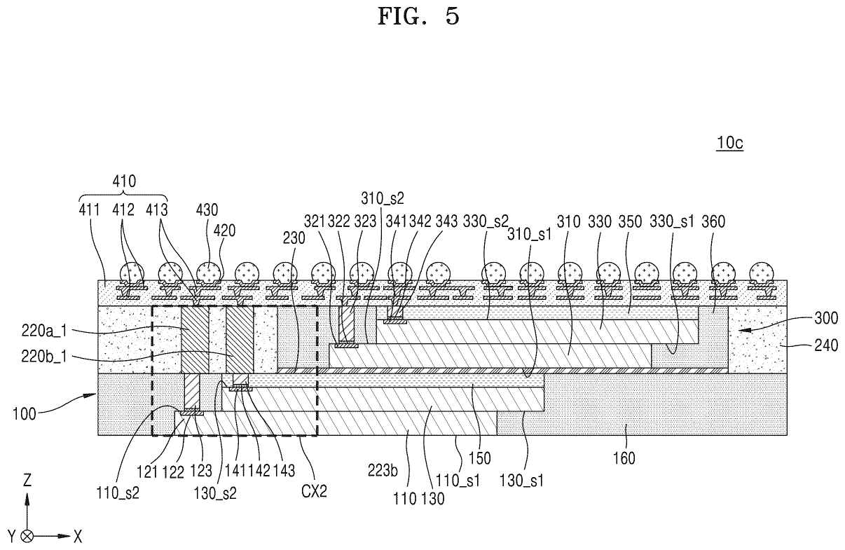

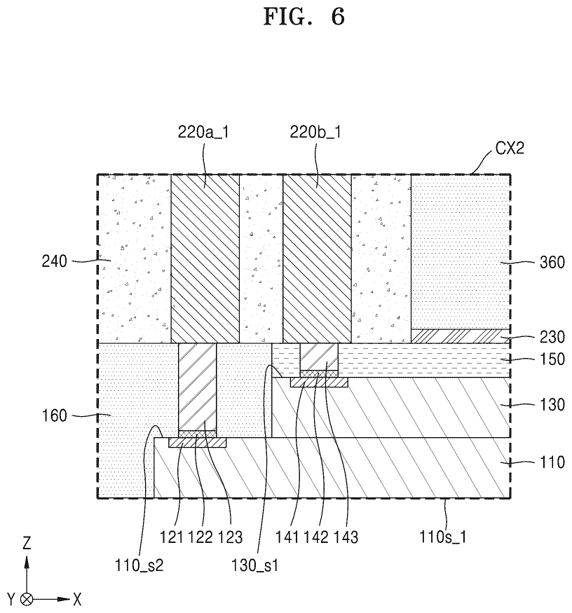

FIG. 5 is a cross-sectional view of a semiconductor package 10c according to another embodiment and FIG. 6 is an enlarged view of area “CX2” in FIG. 5.

The semiconductor package 10c shown in FIGS. 5 and 6 is almost identical or similar to the semiconductor package 10a shown in FIG. 2, except that a die attachment film 230, rather than the PID layer 210, is arranged between the lower semiconductor chip structure 100 and the upper semiconductor chip structure 300 and a first vertical connection conductor 220a_1 is different in shape from a second vertical connection conductor 220b_1. Accordingly, the description of the components already mentioned with reference to FIG. 2 is omitted or simplified.

Referring to FIGS. 5 and 6, the semiconductor package 10c may include the die attachment film 230 positioned between the lower semiconductor chip structure 100 and the upper semiconductor chip structure 300. Unlike the PID layer 210 shown in FIG. 2, the die attachment film 230 does not extend between the outer molding layer 240 and the lower semiconductor chip structure 100.

A lower surface of the die attachment film 230 may be located on the same plane as the lower surface of the outer molding layer 240 and an upper surface of the die attachment film 230 may be in contact with the inactive surface 310_s1 of the first upper die 310. Additionally, a side surface of the die attachment film 230 is in contact with the outer molding layer 240.

Since the die attachment film 230 is less expensive than the PID layer 210 shown in FIG. 2, the semiconductor package 10c shown in FIGS. 5 and 6 may be manufactured at a lower cost than the semiconductor package 10a shown in FIG. 2. The material of the die attachment film 230 is not particularly limited. The die attachment film 230 may include, for example, an epoxy component, but is not limited thereto.

The shapes of the first vertical connection conductor 220a_1 and the second vertical connection conductor 220b_1 shown in FIGS. 5 and 6 may be different from the shapes of the first vertical connection conductor 220a and the second vertical connection conductor 220b shown in FIGS. 2 and 3. The first vertical connection conductor 220a_1 and the second vertical connection conductor 220b_1 shown in FIGS. 5 and 6 may have a single pillar shape. The first vertical connection conductor 220a_1 and the second vertical connection conductor 220b_1 may extend through the outer molding layer 240 in the vertical direction (Z direction). The first vertical connection conductor 220a_1 may be physically and electrically connected to the first lower post 123 and the second vertical connection conductor 220b_1 may be physically and electrically connected to the second lower post 143.

In the case of the semiconductor package 10c shown in FIG. 6, the PID layer 210 shown in FIG. 2 is not formed on the first lower post 123 and the second lower post 143. Thus, the first vertical connection conductor 220a_1 and the second vertical connection conductor 220b_1 may be manufactured to have a simple shape through a simpler process. Therefore, the semiconductor package 10c may be manufactured at a lower cost than the semiconductor package 10a shown in FIG. 2.

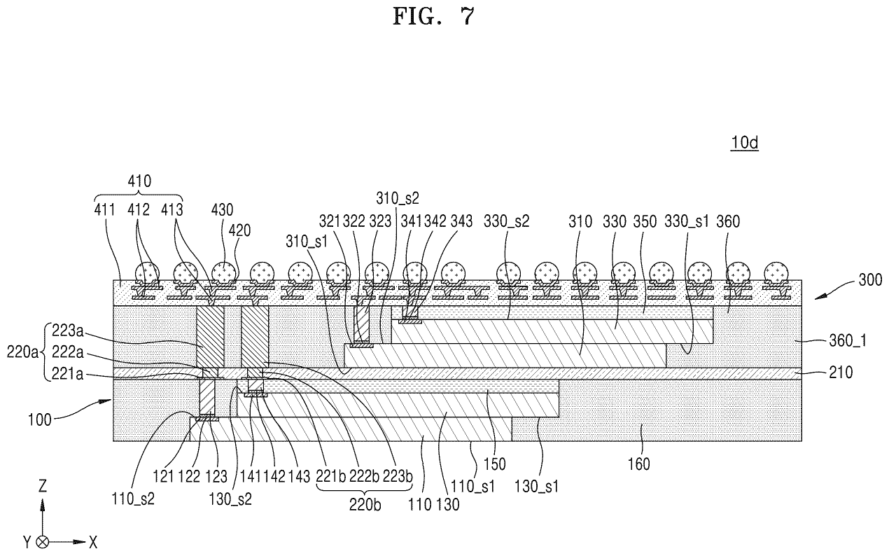

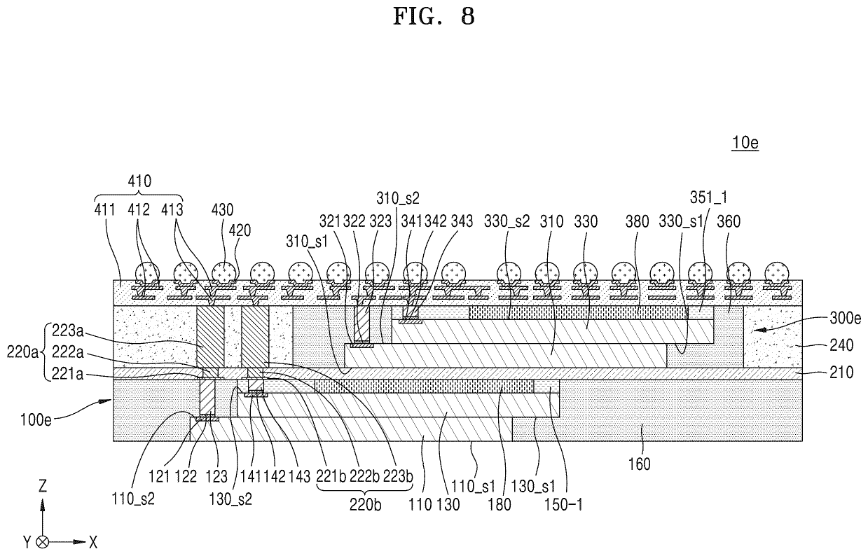

FIGS. 7 and 8 are cross-sectional views of a semiconductor package 10d according to another embodiment.

The semiconductor package 10d shown in FIG. 7 is almost identical or similar to the semiconductor package 10a shown in FIG. 2 except that the sealing configuration of the upper molding layer 360 is different. Accordingly, the description of the components already mentioned with reference to FIG. 2 is omitted or simplified.

The semiconductor package 10d shown in FIG. 7 may include the upper molding layer 360 formed on the PID layer 210. The upper molding layer 360 may seal the first upper die 310, the second upper die 330, the upper insulating layer 350, the first upper post 323, the first vertical connection conductor 220a, and the second vertical connection conductor 220b. Unlike the semiconductor package 10a of FIG. 2, which has a double molding layer structure on the PID layer 210, the semiconductor package 10d of FIG. 7 may have a single molding layer formed on the PID layer 210.

Since the semiconductor package 10d of FIG. 7, unlike the semiconductor package 10a shown in FIG. 2, has a single molding layer, the probability of warpage occurring in the upper molding layer 360 may be reduced.

The semiconductor package 10e shown in FIG. 8 is almost identical or similar to the semiconductor package 10a shown in FIG. 2 except that the semiconductor package 10e further includes dummy bumps 180 and 380. Accordingly, the description of the components already mentioned with reference to FIG. 2 is omitted or simplified.

According to one or more embodiments, a lower semiconductor chip structure 100e may further include a lower dummy bump 180 embedded in a lower insulating layer 150-1. The lower dummy bump 180 may not be connected to the second lower connection pad 141. The lower dummy bump 180 may be placed at the same level as the second lower post 143, wherein an upper surface of the lower dummy bump 180 may be located on the same plane as the upper surface of the second lower post 143 and a lower surface of the lower dummy bump 180 may be located on the same plane as the lower surface of the second lower post 143.

Similarly, an upper semiconductor chip structure 300e may further include a lower dummy bump 380 embedded in the upper insulating layer 350. The lower dummy bump 380 may not be connected to the second upper connection pad 341. The lower dummy bump 380 may be placed at the same level as the second upper post 343, wherein an upper surface of the lower dummy bump 380 may be located on the same plane as the upper surface of the second upper post 343 and a lower surface of the lower dummy bump 380 may be located on the same plane as the lower surface of the second upper post 343.

The lower dummy bump 180 may overlap with at least a portion of an upper semiconductor chip structure 300e in the vertical direction (Z direction) and the lower dummy bump 380 may overlap with at least a portion of the lower semiconductor chip structure 100e in the vertical direction (Z direction).

According to one or more embodiments, the lower dummy bump 380 and the lower dummy bump 180 may have a plate shape. Each of the lower dummy bump 380 and the lower dummy bump 180 may have substantially the same height as the second lower post 143 and the second upper post 343.

The lower dummy bump 180 and the lower dummy bump 380 may improve warpage and maintain flatness of the semiconductor package 10e. In addition, the lower dummy bump 180 may easily dissipate heat generated from the first lower die 110 and the second lower die 130 to the outside and the lower dummy bump 380 may easily dissipate heat generated from the first upper die 310 and the second upper die 330 to the outside.

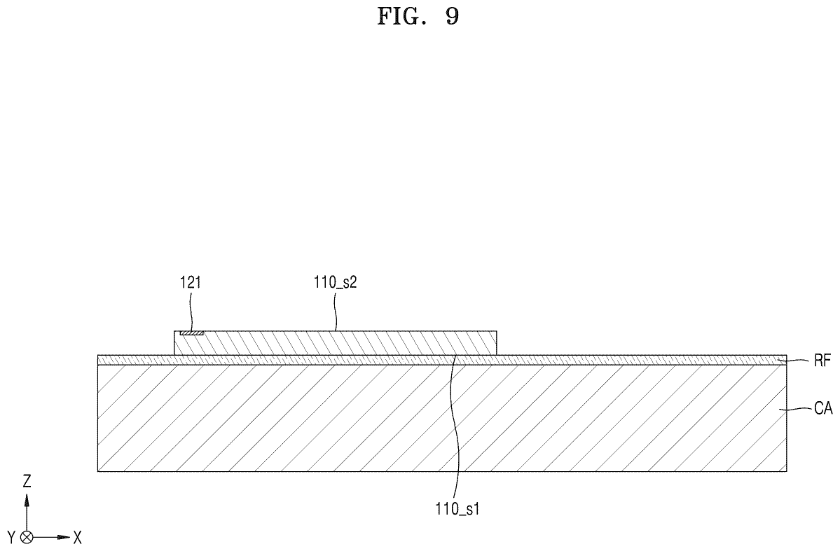

FIGS. 9 to 26 are cross-sectional views sequentially illustrating a manufacturing process of the semiconductor package 10b shown in FIG. 4.

Referring to FIG. 9, the process may include attaching the first lower die 110 to a carrier substrate CA to which a release film RF is attached.

The carrier substrate CA may include any material that is stable against baking processes, etching processes, and the like. When the carrier substrate CA is to be separated and removed later by laser ablation, the carrier substrate CA may include a light-transmissive substrate. Optionally, when the carrier substrate CA is to be separated and removed by heating later, the carrier substrate CA may include a heat-resistant substrate.

In one or more embodiments, the carrier substrate CA may include a glass substrate. Alternatively, in another embodiment, the carrier substrate CA may include a heat-resistant organic polymer material, such as PI, polyetheretherketone (PEEK), polyethersulfone (PES), and polyphenylene sulfide (PPS) but is not limited thereto.

For example, the release film RF may include a laser-responsive layer which enables the carrier substrate CA to be separated by being vaporized in response to subsequent laser irradiation. The release film RF may include a carbon-based material layer. For example, the release film RF may include an amorphous carbon layer (ACL). The release film RF may include any material capable of fixing the first lower die 110.

According to one or more embodiments, the first lower die 110 may be disposed on the release film RF. An inactive surface 110_s1 of the first lower die 110 may be attached to an upper surface of the release film RF and an active surface 110_s2 of the first lower die 110 may be arranged to face the top.

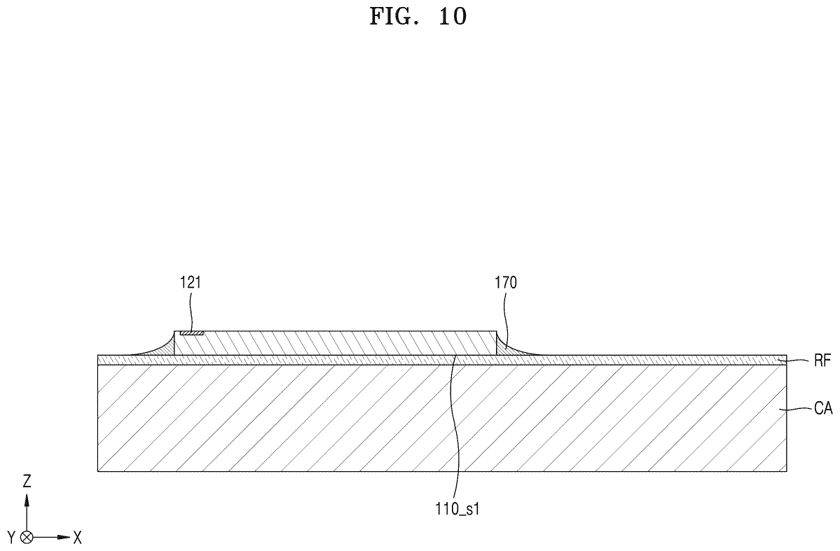

Referring to FIG. 10, the lower side support layer 170 may be formed on the side surfaces of the first lower die 110 attached to the release film RF. The lower side support layer 170 may be formed using, for example, a dispenser. A polymer-based adhesive material may be injected into the side surfaces of the first lower die 110 by using the dispenser. Thereafter, when the adhesive material is cured, the lower side support layer 170 that contacts the side surfaces of the first lower die 110 and the release film RF may be formed. At this time, the lower side support layer 170 may be formed so as not to contact the upper surface of the first lower die 110.

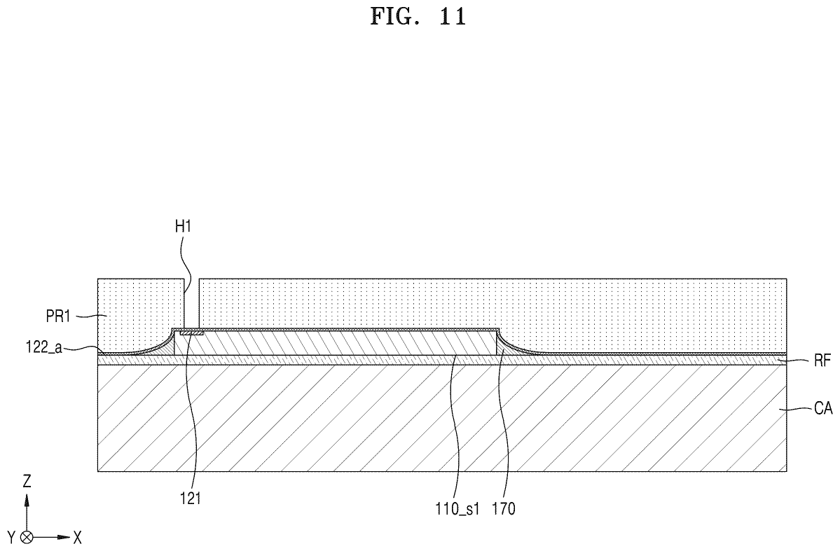

Referring to FIG. 11, a lower metal seed material 122_a may be deposited on the release film RF and the first lower die 110. The lower metal seed material 122_a may be formed to conformally cover the lower side support layer 170, the first lower connection pad 121, and the active surface 110_s2 of the first lower die 110. According to one or more embodiments, the lower metal seed material 122_a may be formed by using electrolytic plating or electroless plating.

Thereafter, a first mask layer PR1 may be formed to cover the lower metal seed material 122_a and a first vertical hole H1 may be formed by removing a portion of the first mask layer PR1 so that a portion of an upper surface of the lower metal seed material 122_a is exposed.

The first mask layer PR1 may be formed by a method of laminating and then curing a precursor or a method of spreading and then curing precursor material. The first vertical hole H1 may be formed in the first mask layer PR1 by using a photolithography method, a mechanical drill, and/or a laser drill. The first mask layer PR1 may include an insulating material, such as PID. As the first vertical hole H1 is formed, a portion of the upper surface of the lower metal seed material 122_a may be exposed. The first vertical hole H1 may overlap with the first lower connection pad 121 in the vertical direction (Z direction).

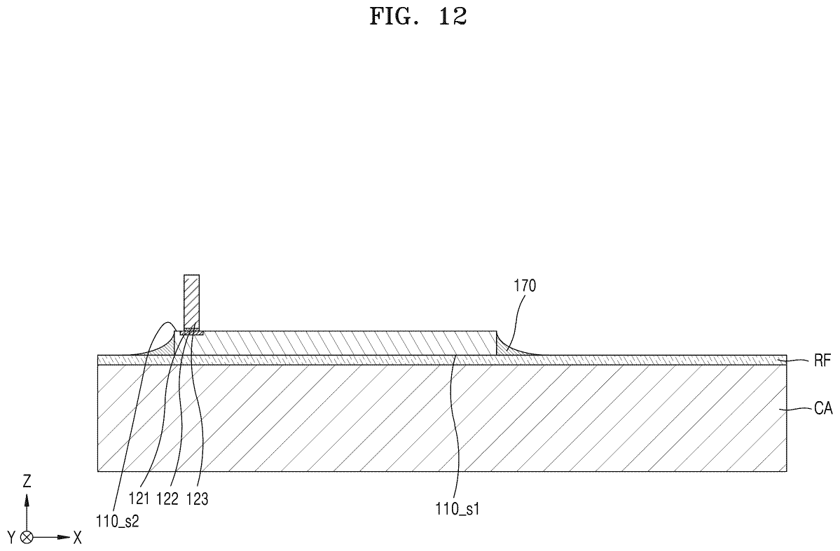

Referring to FIGS. 11 and 12, the first lower post 123 may be formed to fill the first vertical hole H1 of the first mask layer PR1 and then the first mask layer PR1 and a portion of the lower metal seed material 122_a of which the upper surface is not exposed may be removed together. As the portion of the lower metal seed material 122_a is also removed, only a seed layer that completely overlaps with the first lower post 123 in the vertical direction (Z direction) may remain. Thus, the seed layer that completely overlaps the first lower post 123 in the vertical direction (Z direction) may be defined as the first lower metal seed layer 122.

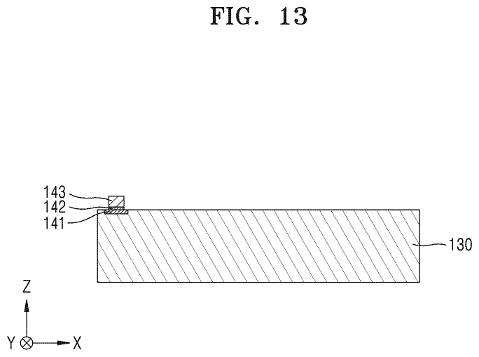

Referring to FIG. 13, the second lower die 130 with the second lower connection pad 141 formed on the active surface thereof is provided. The second lower post 143 extending in the vertical direction (Z direction) may be formed on the second lower connection pad 141 of the second lower die 130. The second lower post 143 may be formed in a similar manner to the method of forming the first lower post 123 described with reference to FIGS. 10 to 12.

Referring to FIG. 14, an insulating material 151 may coat the active surface of the second lower die 130. Since the second lower post 143 protrudes from the active surface of the second lower die 130 in the vertical direction (Z direction), the protrusion 151_u of the insulating material 151 covering the second lower post 143 may also protrude in the vertical direction (Z direction).

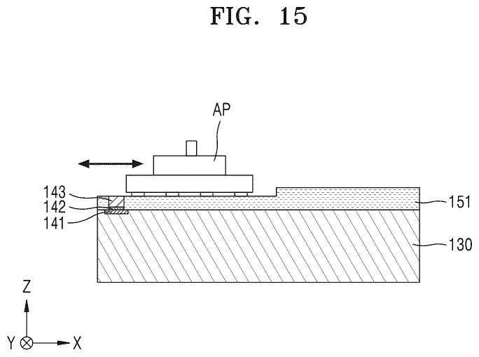

Referring to FIG. 15, the insulating material 151 may be flattened so that the second lower post 143 is exposed. The flattening of the insulating material 151 may include a grinding process using grinding equipment AP.

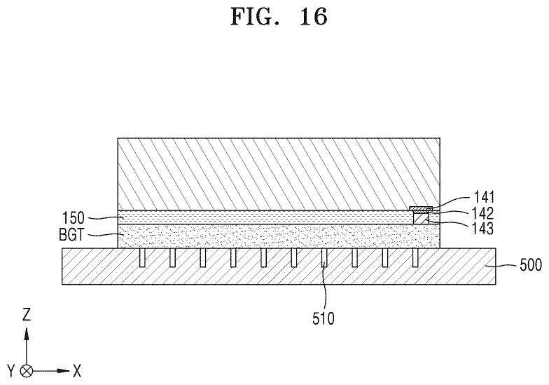

Referring to FIG. 16, the second lower die 130 may be placed on a vacuum chuck 500. A back grinding tape BGT may be attached to an upper surface of the vacuum chuck 500 and may be arranged to face the active surface of the second lower die 130. The back grinding tape BGT may be a tape which is capable of fixing the second lower die 130 during the back grinding process. For example, the back grinding tape BGT may include a tape having an epoxy component. The second lower die 130 may be fixed more stably and reliability may be improved through the back grinding tape BGT.

A plurality of vacuum holes 510 arranged in the lateral direction (X direction and/or Y direction) may be disposed in the upper surface of the vacuum chuck 500. The plurality of vacuum holes 510 may be configured to fix the back grinding tape BGT to the vacuum chuck 500 through vacuum suction so that the back grinding tape BGT is not detached from the vacuum chuck 500.

According to one or more embodiments, since the active surface of the second lower die 130 is arranged to face the back grinding tape BGT, the upper surface of the second lower post 143 exposed to the lower insulating layer 150 may be attached to the back grinding tape BGT.

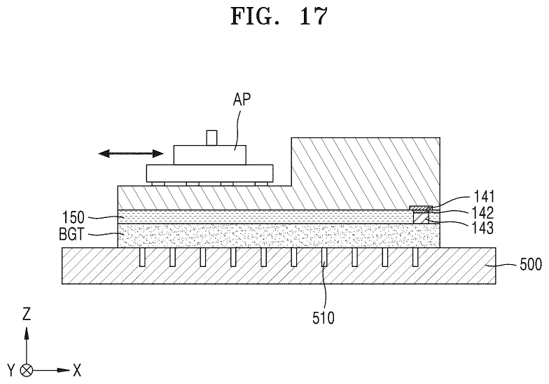

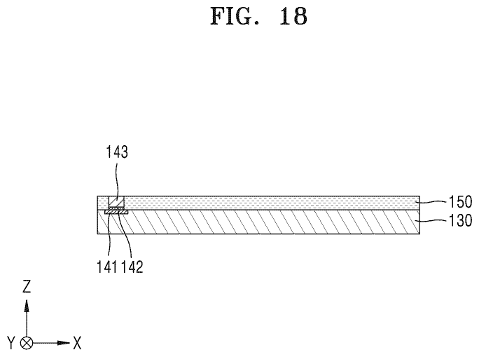

Referring to FIGS. 17 and 18, the inactive surface of the second lower die 130 fixed to the vacuum chuck 500 may be flattened. The flattening of the second lower die 130 may include the grinding process using the grinding equipment AP.

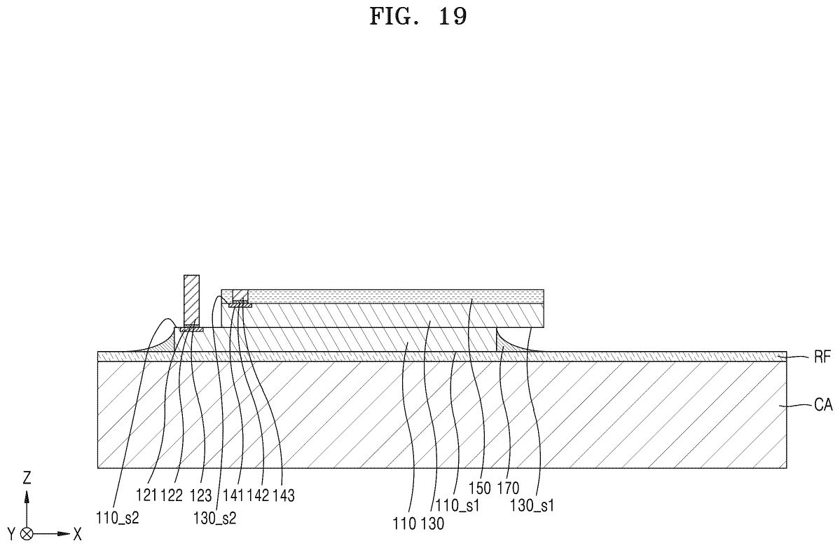

Referring to FIG. 19, the second lower die 130 may be attached to the first lower die 110. The inactive surface 130_s1 of the second lower die 130 may be arranged to face the active surface 110_s2 of the first lower die 110. The first lower die 110 and the second lower die 130 may be stacked in steps. The first lower die 110 and the second lower die 130 may be horizontally offset so that the first lower connection pad 121 and the second lower connection pad 141 are exposed. For example, the first lower die 110 and the second lower die 130 may be horizontally offset and stacked toward one corner of the carrier substrate CA.

The first lower post 123 may be spaced apart from the second lower die 130 in the first horizontal direction (X direction) and the vertical level of the upper surface of the first lower post 123 may be greater than the vertical level of the upper surface of the second lower post 143.

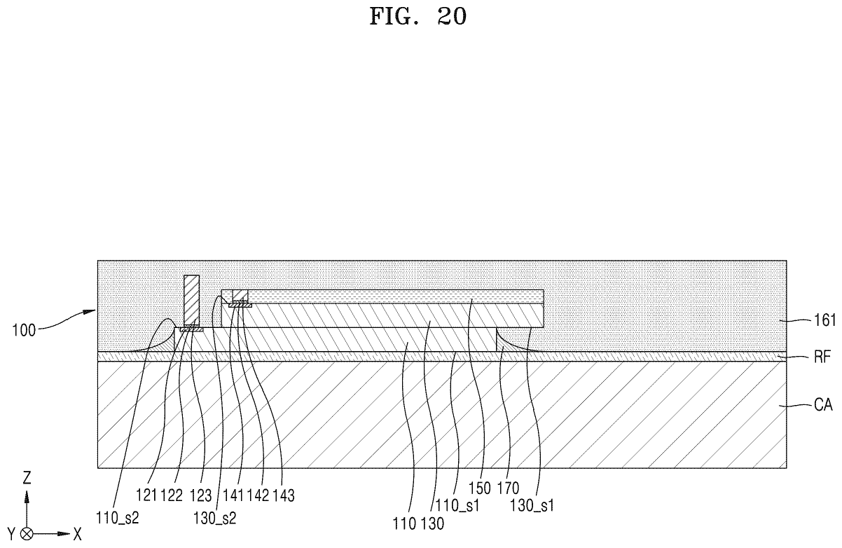

Referring to FIG. 20, a first molding material 161 covering the first lower die 110, the second lower die 130, the first lower post 123, and the release film RF may be formed.

The first molding material 161 may be formed to cover the active surface 110_s2 of the first lower die 110 and the upper surface of the lower insulating layer 150. Additionally, the first molding material 161 may cover the side surfaces of the second lower die 130 and the side surfaces of the lower insulating layer 150.

The forming of the first molding material 161 may include laminating and then curing the precursor of the first molding material 161. In another embodiment, the first molding material 161 may be spread and then cured to seal the first lower die 110 and the second lower die 130. The first lower die 110 and the second lower die 130 may be fixed by curing.

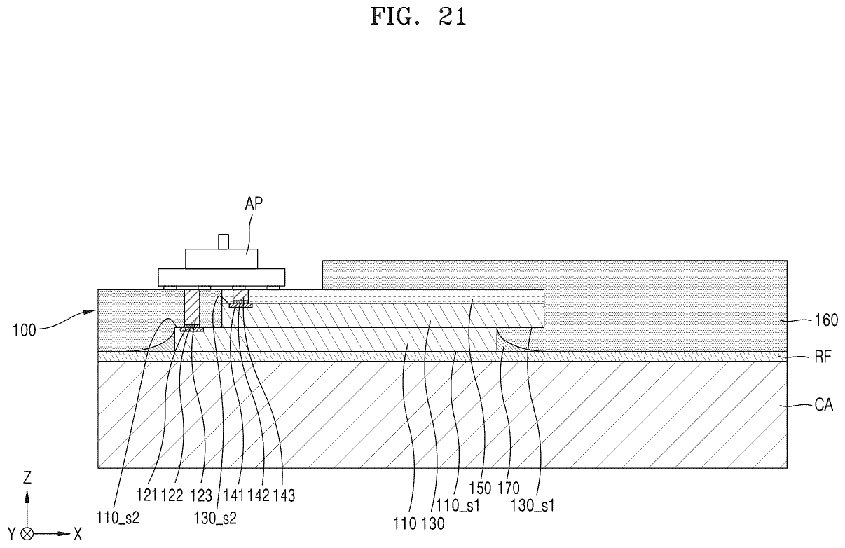

Referring to FIG. 21, the first molding material 161 may be flattened so that the first lower post 123, the second lower post 143, and the lower insulating layer 150 are exposed.

The flattening of the first molding material 161 may include using a grinding process. In this process, the upper surface of the first lower post 123, the upper surface of the second lower post 143, and the upper surface of the lower insulating layer 150 may all be located on the same plane. When the process of flattening the first molding material 161 is completed, the lower molding layer 160 is completed.

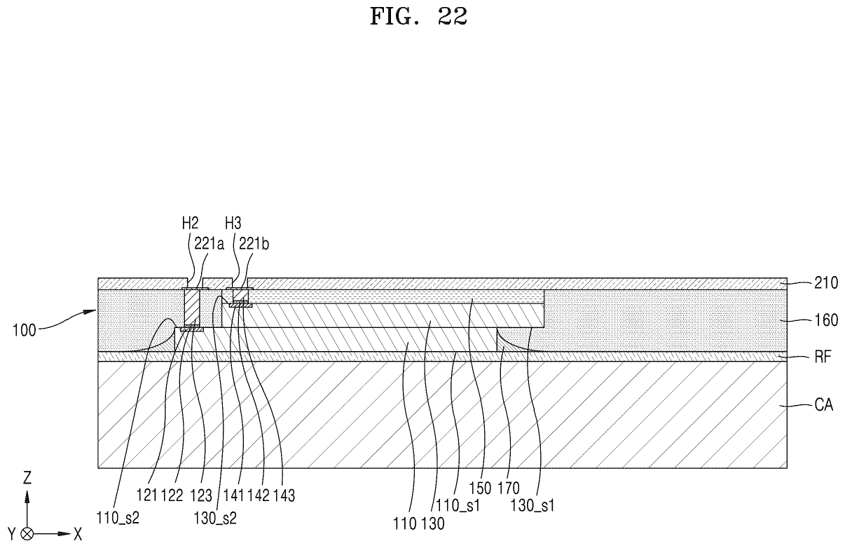

Referring to FIG. 22, after forming the first vertical connection pad 221a and the second vertical connection pad 221b, the PID layer 210 may be formed on the lower insulating layer 150. The lower surface of the PID layer 210 may be in contact with the lower insulating layer 150 and the lower molding layer 160. The first vertical connection pad 221a may be placed in contact with the first lower post 123 and the second vertical connection pad 221b may be placed in contact with the second lower post 143. In one or more embodiments, the width of the first vertical connection pad 221a in the lateral direction (X direction and/or Y direction) may be greater than the width of the first lower post 123 in the lateral direction (X direction and/or Y direction) and the width of the second vertical connection pad 221b in the lateral direction (X direction and/or Y direction) may be greater than the width of the second lower post 143 in the lateral direction (X direction and/or Y direction).

The PID layer 210 may include a photosensitive insulating material and may be formed through, for example, a deposition process. However, the process of forming the PID layer 210 is not limited to the above.

After forming the PID layer 210, a second vertical hole H2 and a third vertical hole H3 may be formed by removing a portion of the PID layer 210 to expose a portion of the upper surface of the first vertical connection pad 221a and a portion of the upper surface of the second vertical connection pad 221b.

The second vertical hole H2 and the third vertical hole H3 may be formed in the PID layer 210 by using a photolithography method. As the second vertical hole H2 is formed, a portion of the upper surface of the first vertical connection pad 221a may be exposed. As the third vertical hole H3 is formed, a portion of the upper surface of the second vertical connection pad 221b may be exposed. The second vertical hole H2 may overlap with the first vertical connection pad 221a in the vertical direction (Z direction) and the third vertical hole H3 may overlap with the second vertical connection pad 221b in the vertical direction (Z direction).

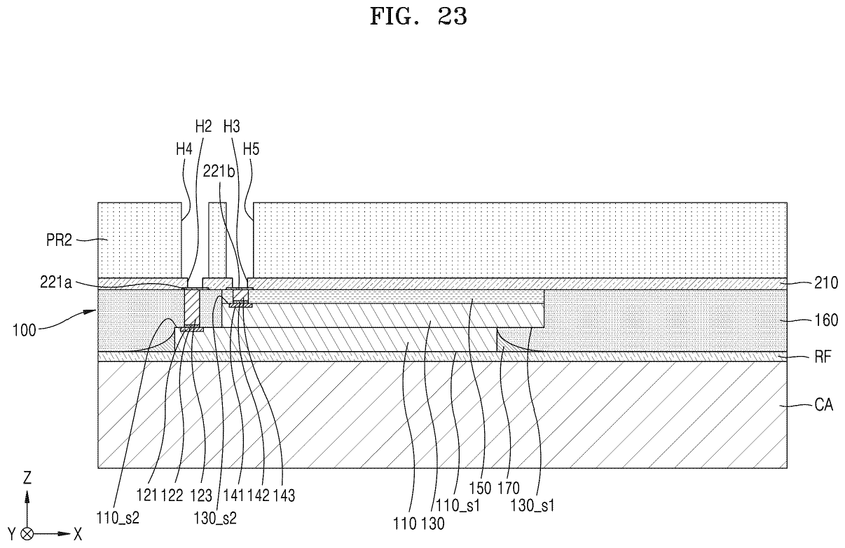

Referring to FIG. 23, a second mask layer PR2 may be formed to cover the PID layer 210 and then a fourth vertical hole H4 and a fifth vertical hole H5 may be formed by removing a portion of the first mask layer PR1 to expose a portion of the upper surfaces of the first vertical connection pad 221a and the second vertical connection pad 221b.

The fourth vertical hole H4 may be formed to overlap with the second vertical hole H2 and the fifth vertical hole H5 may be formed to overlap with the third vertical hole H3. The diameter of the fourth vertical hole H4 in the lateral direction (X direction and/or Y direction) may be greater than the diameter of the second vertical hole H2 in the lateral direction (X direction and/or Y direction) and the diameter of the fifth vertical hole H5 in the lateral direction (X direction and/or Y direction) may be greater than the diameter of the third vertical hole H3 in the lateral direction (X direction and/or Y direction). In addition, the length of the fourth vertical hole H4 in the vertical direction (Z direction) may be greater than the length of the second vertical hole H2 in the vertical direction (Z direction) and the length of the fifth vertical hole H5 in the vertical direction (Z direction) may be greater than the length of the third vertical hole H3 in the vertical direction (Z direction).

The second mask layer PR2 may be formed by a method of laminating and then curing a precursor or a method of spreading and then curing precursor material. The fourth vertical hole H4 and the fifth vertical hole H5 may be formed in the second mask layer PR2 by using a photolithography method, a mechanical drill, and/or a laser drill. The second mask layer PR2 may include an insulating material, such as photosensitive insulating resin. As the fourth vertical hole H4 and the fifth vertical hole H5 are formed, a portion of the upper surfaces of the first vertical connection pad 221a and the second vertical connection pad 221b may be exposed. The fourth vertical hole H4 may overlap with the first vertical connection pad 221a in the vertical direction (Z direction) and the fifth vertical hole H5 may overlap with the second vertical connection pad 221b in the vertical direction (Z direction).

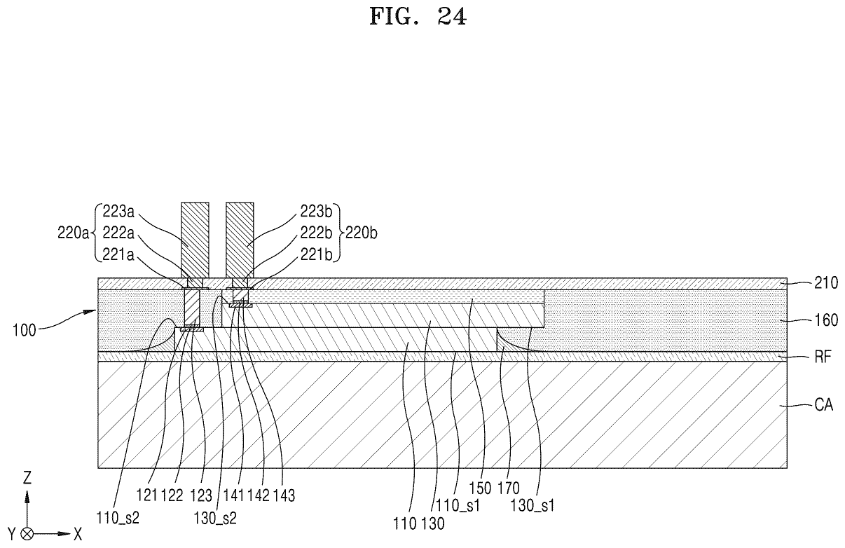

Referring to FIG. 24, the first lower vertical connection post 222a and the second lower vertical connection post 222b may be formed by filling the second vertical hole H2 and the third vertical hole H3 of the PID layer 210 with the conductive material. In addition, the first upper vertical connection post 223a and the second upper vertical connection post 223b may be formed by filling the fourth vertical hole H4 and the fifth vertical hole H5 of the second mask layer PR2 with the conductive material. Since the second vertical hole H2 overlaps with the fourth vertical hole H4, the first lower vertical connection post 222a and the first upper vertical connection post 223a may be formed continuously by injecting the conductive material into the fourth vertical hole H4. Similarly, since the third vertical hole H3 overlaps with the fifth vertical hole H5, the second lower vertical connection post 222b and the second upper vertical connection post 223b may be formed continuously by injecting the conductive material into the fifth vertical hole H5. After the first lower vertical connection post 222a, the second lower vertical connection post 222b, the first upper vertical connection post 223a, and the second upper vertical connection post 223b are formed, the second mask layer PR2 may be removed. The first vertical connection conductor 220a may be completed by forming the first lower vertical connection post 222a and the first upper vertical connection post 223a and the second vertical connection conductor 220b may be completed by forming the second lower vertical connection post 222b and the second upper vertical connection post 223b.

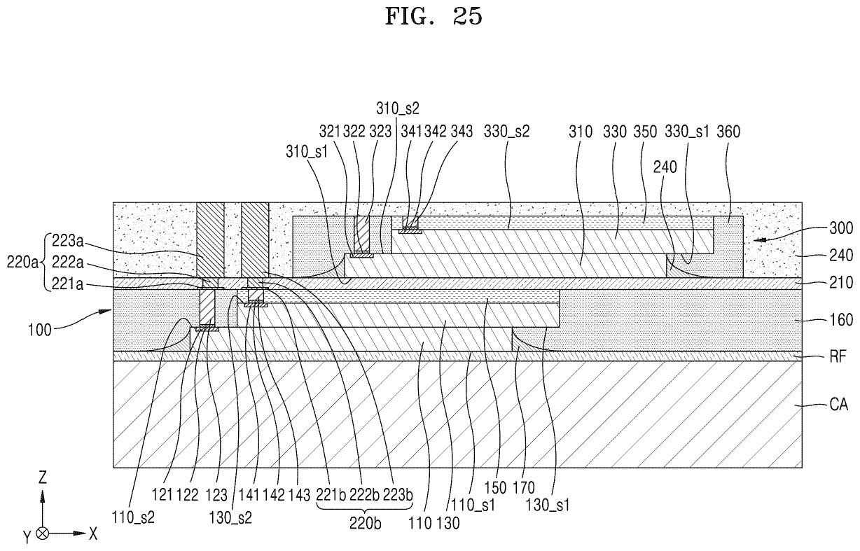

Referring to FIG. 25, the outer molding layer 240 configured to seal the first upper vertical connection post 223a, the second upper vertical connection post 223b, and the upper semiconductor chip structure 300 may be formed.

The outer molding layer 240 may be formed to cover the upper surface of the PID layer 210. Additionally, the outer molding layer 240 may cover the side surfaces of the first upper vertical connection post 223a, the side surfaces of the second upper vertical connection post 223b, and the side surfaces of the upper semiconductor chip structure 300.

The forming of the outer molding layer 240 may include laminating and then curing a molding material precursor. In another embodiment, the molding material may be spread and then cured to seal the upper semiconductor chip structure 300. The upper semiconductor chip structure 300 may be fixed onto the PID layer 210 by curing.

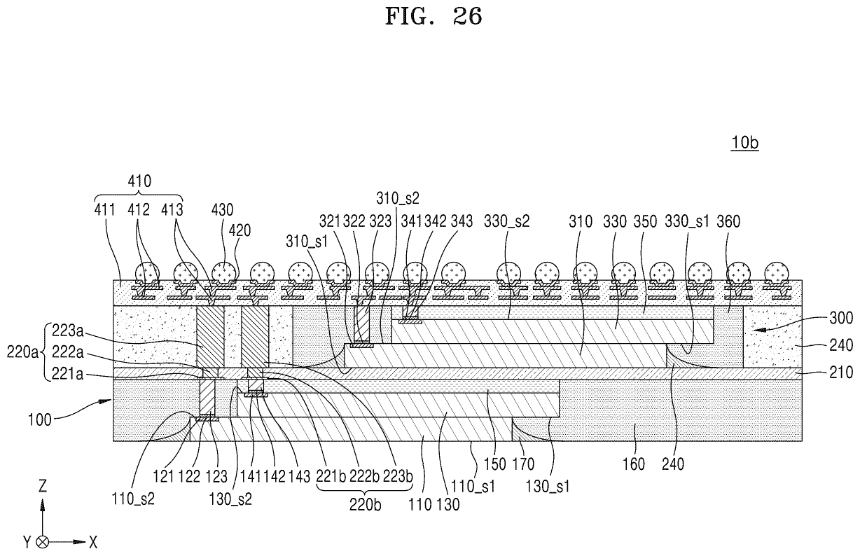

Referring to FIG. 26, the redistribution structure 410 may be formed on the outer molding layer 240. The redistribution structure 410 may include the redistribution insulating layer 411, the plurality of redistribution layers 412, and the plurality of redistribution vias 413. At least some of the plurality of redistribution layers 412 or at least some of the plurality of redistribution vias 413 may contact the first upper vertical connection post 223a, the second upper vertical connection post 223b, the first upper post 323, and the second upper post 343. In one or more embodiments, the plurality of redistribution vias 413 may have a tapered shape in which the horizontal width thereof increases from the bottom to the top. That is, the horizontal width of the plurality of redistribution vias 413 increases as the distance from the upper semiconductor chip structure 300 increases. Additionally, some of the plurality of redistribution layers 412 may be arranged at different vertical levels. The redistribution insulating layer 411 may be formed by using a lamination or spreading method. Thereafter, via holes may be formed in the redistribution insulating layer 411, wherein the redistribution layers 412 and the redistribution vias 413 may be formed by using electrolytic plating or electroless plating. When using PID as the redistribution insulating layer 411, the via holes may be formed at a fine pitch by using a photolithography method.

After forming the redistribution structure 410, the under bump metal layers 420 may be formed in contact with redistribution layers 412 located at the top among the plurality of redistribution layers 412. Openings may be formed in the redistribution insulating layer 411 and the under bump metal layers 420 may be formed in the openings. Afterwards, the external connection terminals 430 may be formed on the under bump metal layers 420. As a result, the semiconductor package 10b of FIG. 4 may be manufactured.

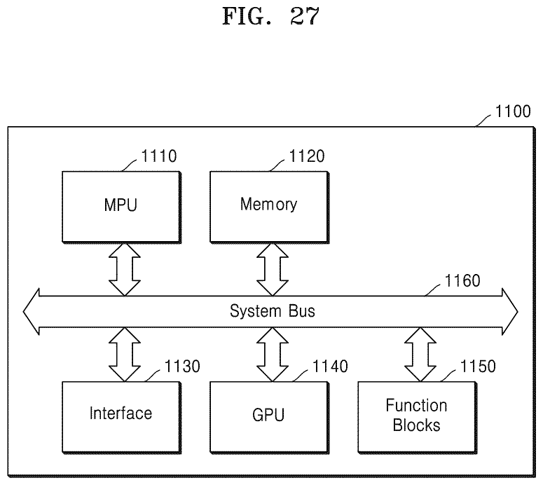

FIG. 27 is a schematic block diagram of a semiconductor package according to one or more embodiments.

Specifically, a semiconductor package 1100 may include a microprocessing unit 1110, memory 1120, an interface 1130, a graphics processing unit 1140, functional blocks 1150, and a bus 1160 connecting the same. The semiconductor package 1100 may include one or both of the microprocessing unit 1110 and the graphics processing unit 1140.

The microprocessing unit 1110 may include a core and an L2 cache. For example, the microprocessing unit 1110 may include multi-core. Each core of the multi-core may have the same or different performance. Additionally, each core of the multi-core may be activated at the same time or at different times. The memory 1120 may store the results of processing in the functional blocks 1150 under the control by the microprocessing unit 1110. For example, the microprocessing unit 1110 may store content stored in the L2 cache in the memory 1120 as the content is flushed. The interface 1130 may interface with external devices. For example, the interface 1130 may interface with a camera, an LCD, and a speaker.

The graphics processing unit 1140 may perform graphics functions. For example, the graphics processing unit 1140 may perform video codec or process 3D graphics. The functional blocks 1150 may perform various functions. For example, when the semiconductor package 1100 is an AP used in a mobile device, some of the functional blocks 1150 may perform a communication function.

The semiconductor package 1100 may include any one of the semiconductor packages 10a-10e previously illustrated above. The microprocessing unit 1110 and/or the graphics processing unit 1140 may include any one of the semiconductor packages 10a-10e illustrated above. The memory 1120 may include any one of the semiconductor packages 10a-10e illustrated above. The interface 1130 and the functional blocks 1150 may include any one of the semiconductor packages 10a-10e illustrated above.

While the inventive concept has been particularly shown and described with reference to one or more embodiments thereof, it will be understood that various changes in form and details may be made therein without departing from the spirit and scope of the following claims.

What is claimed is:

1. A semiconductor package comprising:
a lower semiconductor chip structure comprising:
a plurality of lower dies stacked in a vertical direction;
a lower post extending in the vertical direction from an upper surface of a lower die among the plurality of lower dies; and
an insulating layer surrounding the lower post;
an upper semiconductor chip structure above the lower semiconductor chip structure; and
a vertical connection conductor on the lower semiconductor chip structure, wherein the vertical connection conductor is spaced apart from the upper semiconductor chip structure in a horizontal direction and is connected to the lower post.

2. The semiconductor package of claim 1,
wherein the lower semiconductor chip structure comprises a plurality of lower posts including the lower post,
wherein the plurality of lower posts extend in the vertical direction from upper surfaces of the plurality of lower dies,
wherein each of the plurality of lower dies comprises a lower connection pad connected to at least one lower post of the plurality of lower posts, and
wherein the plurality of lower dies are stacked and offset in the horizontal direction such that the lower connection pad of each respective lower die of the plurality of lower dies is exposed on the upper surface of the respective lower die.

3. The semiconductor package of claim 2, further comprising a metal seed layer between each of the lower connection pads and each of the plurality of lower posts, wherein the metal seed layer is in contact with each of the plurality of lower posts.

4. The semiconductor package of claim 1,
wherein a lower surface of the insulating layer is coplanar with an upper surface of an uppermost lower die among the plurality of lower dies, and
wherein an edge of the insulating layer coincides with an edge of the uppermost lower die.

5. The semiconductor package of claim 1,
wherein the lower semiconductor chip structure comprises a second lower post,
wherein the plurality of lower dies comprises a first lower die and a second lower die on the first lower die,
wherein the lower post extends from an upper surface of the first lower die in the vertical direction and the second lower post extends from an upper surface of the second lower die in the vertical direction, and
wherein a length of the lower post in the vertical direction is greater than a length of the second lower post in the vertical direction.

6. The semiconductor package of claim 1, further comprising a photo imageable dielectric (PID) layer between the lower semiconductor chip structure and the upper semiconductor chip structure and surrounding at least a portion of the vertical connection conductor.

7. The semiconductor package of claim 1,
wherein the upper semiconductor chip structure comprises a plurality of upper dies stacked in the vertical direction and an upper molding layer sealing the plurality of upper dies, and
wherein the semiconductor package further comprises an outer molding layer that seals the upper semiconductor chip structure and the vertical connection conductor.

8. The semiconductor package of claim 1, further comprising a redistribution structure on the upper semiconductor chip structure, wherein the redistribution structure is connected to the upper semiconductor chip structure and the vertical connection conductor.

9. The semiconductor package of claim 1, wherein a maximum width of the lower post is less than a maximum width of the vertical connection conductor.

10. The semiconductor package of claim 1, further comprising:
a lower molding layer sealing the plurality of lower dies; and
a side support layer in contact with a side surface of a lowermost lower die among the plurality of lower dies,
wherein the lower molding layer is in contact with a side surface of a lower die stacked on the lowermost lower die among the plurality of lower dies.

11. A semiconductor package comprising:
a lower memory chip structure comprising;
a first lower die;
a second lower die stacked on the first lower die a vertical direction;
a first lower post extending from an upper surface of the first lower die in the vertical direction;
a second lower post extending from an upper surface of the second lower die in the vertical direction; and
an insulating layer extending along the upper surface of the second lower die and surrounding the second lower post;
an upper memory chip structure on the lower memory chip structure;
a first vertical connection conductor on the lower memory chip structure, wherein the first vertical connection conductor is spaced apart from the upper memory chip structure in a horizontal direction and is connected to the first lower post; and
a second vertical connection conductor on the lower memory chip structure, wherein the second vertical connection conductor is spaced apart from the first vertical connection conductor in the horizontal direction and is connected to the second lower post.

12. The semiconductor package of claim 11, wherein an upper surface of the second lower post is coplanar with an upper surface of the insulating layer.

13. The semiconductor package of claim 11, further comprising a die attachment film extending along a lower surface of the upper memory chip structure, wherein the die attachment film extends along at least a portion of an upper surface of the insulating layer.

14. The semiconductor package of claim 11,
wherein the upper memory chip structure comprises a first upper die and a second upper die which are stacked in the vertical direction, and
wherein the semiconductor package further comprises an upper molding layer sealing the first upper die, the second upper die, the first vertical connection conductor, and the second vertical connection conductor.

15. The semiconductor package of claim 11, wherein the lower memory chip structure further comprises a dummy bump surrounded by the insulating layer, wherein the dummy bump overlaps with at least a portion of the upper memory chip structure in the vertical direction.

16. The semiconductor package of claim 11, further comprising an outer molding layer that seals the upper memory chip structure, the first vertical connection conductor, and the second vertical connection conductor,
wherein the first vertical connection conductor and the second vertical connection conductor each comprise a pillar with a length in the vertical direction equal to a length of the outer molding layer in the vertical direction, and wherein each of the pillars have a constant width along the length in the vertical direction.

17. The semiconductor package of claim 11, further comprising a redistribution structure on the upper memory chip structure,
wherein the upper memory chip structure comprises:
a plurality of upper dies stacked in the vertical direction; and
a plurality of upper posts extending from upper surfaces of the plurality of upper dies in the vertical direction, wherein the plurality of upper posts are connected to the redistribution structure.

18. A semiconductor package comprising:
a lower memory chip structure comprising:
a first lower die;
a second lower die stacked on the first lower die in a vertical direction;
a first lower post extending from an upper surface of the first lower die in the vertical direction;
a second lower post extending from an upper surface of the second lower die in the vertical direction; and
an insulating layer extending along the upper surface of the second lower die and surrounding the second lower post;
an upper memory chip structure on the lower memory chip structure;
a photo imageable dielectric (PID) layer between the upper memory chip structure and the lower memory chip structure;
an outer molding layer sealing the upper memory chip structure;
a redistribution structure on the upper memory chip structure;
a first vertical connection conductor passing through the PID layer and the outer molding layer to connect the first lower post to the redistribution structure; and
a second vertical connection conductor passing through the PID layer and the outer molding layer to connect the second lower post to the redistribution structure,
wherein the insulating layer is between the PID layer and the second lower die.

19. The semiconductor package of claim 18, wherein a length of the first vertical connection conductor in the vertical direction is equal to a length of the second vertical connection conductor in the vertical direction.

20. The semiconductor package of claim 18, wherein each of the first vertical connection conductor and the second vertical connection conductor comprises a lower vertical connection post embedded in the PID layer. and an upper vertical connection post having a diameter from a diameter of the lower vertical connection post, wherein each upper vertical connection post is embedded in the outer molding layer.
